(19) United States
(12) Patent Application Publication
(10) Pub. No.: US 2026/0072136 A1
(43) Pub. Date: Mar. 12, 2026

(54) OPTICAL SENSOR

(71) Applicant: OMRON Corporation, Kyoto-shi (JP)

(72) Inventors: Kazunari Komai, Kyoto-shi (JP); Tsuyoshi Miyata, Kyoto-shi (JP); Motoharu Okuno, Kyoto-shi (JP); Katsushi Takaichi, Kyoto-shi (JP); Motoki Tanaka, Kyoto-shi (JP)

(21) Appl. No.: 19/303,703

(22) Filed: Aug. 19, 2025

(30) Foreign Application Priority Data
Sep. 11, 2024 (JP) 2024-157437

(51) Int. Cl. G01S 7/481; G01S 17/04; H10H 20/855

(52) U.S. Cl. CPC G01S 7/4814; G01S 7/4813; G01S 17/04; H10H 20/855

(57) ABSTRACT

An optical sensor includes a light projecting unit, a light receiving unit, and a detection unit. The light projecting unit includes a light source that emits light and the light projecting lens configured to condense the light emitted from the light source. The light receiving unit receives the light, and the detection unit detects a target object based on the received light. The light projecting unit further includes a package having a recessed portion. The light source is mounted on the bottom surface of the recessed portion. The light projecting unit also includes a resin that is light transmissive and covers the light source. A side surface of the recessed portion includes a material that absorbs the light emitted from the light source.

This application claims the benefit of priority to Japanese Patent Application Number 2024-157437 filed on Sep. 11, 2024. The entire contents of the above-identified application are hereby incorporated by reference.

### TECHNICAL FIELD

The present disclosure relates to an optical sensor.

### BACKGROUND ART

There are two types of optical sensors, one for detecting an object based on the magnitude of amount of received light and the other for detecting an object by converting distribution of amount of received light into the object position. As a specific example of the latter, JP 2007-221491 A is known.

This document describes that after the optical sensor obtains distribution of amount of received light, when multiple peaks are detected in this distribution, it is determined that multiple reflections have occurred and thus an object exists. On the other hand, even when the peak is not detected, it is determined that an object exists due to the change in the state of received light.

Furthermore, even when only one peak is present but its position exceeds a threshold range, it is determined that an object exists.

In addition, even when the width of the received light waveform exceeds a specified range, it is determined that an object exists. This optical sensor allows for executing control according to the presence or absence of multiple reflections, by detecting the presence or absence of multiple reflections based on the distribution of amount of received light, and outputting a signal related to the presence or absence of multiple reflections.

### BRIEF SUMMARY

In the related art, the light projecting unit of an optical sensor has been employing a package product that integrates a light source and a package, which are widely distributed in the market.

However, when such a package product is used as it is, light from the light source is reflected on the package, or the like, and unintended light in the design, that is, stray light, is generated. In order to prevent this stray light from affecting the performance of the optical sensor, measures such as reducing the amount of light emitted from the light source have been taken in the related art. As a result, the known measures have caused a decrease in the signal-to-noise ratio (hereinafter also referred to as “S/N ratio”: Signal-to-Noise Ratio).

The present disclosure has been made in view of such circumstances. The present disclosure provides an optical sensor capable of reducing stray light.

As described herein, an optical sensor includes a light projecting unit,
a light receiving unit, and a detection unit.

The light projecting unit includes a light source that emits light and a light condensing element configured to condense the light emitted from the light source.

The light receiving unit receives the light, and the detection unit detects a target object based on the received light.

The light projecting unit further includes a package formed with a recessed portion.

The light source is mounted on the bottom surface of the recessed portion.

The light projecting unit also includes a resin that is light transmissive and covers the light source.

A side surface of the recessed portion includes a material that absorbs the light emitted from the light source.

According to this aspect, the light projecting unit further includes a package formed with a recessed portion having a bottom surface on which the light source is mounted, and a resin that is light transmissive and covers the light source, and a side surface of the recessed portion includes a material that absorbs the light emitted from the light source. As a result, the light emitted from the light source installed on the bottom surface and incident on the side surface is absorbed, making it possible to reduce stray light that passes through the side surface, which is the main factor in stray light generation. Therefore, stray light can be reduced, and a decrease in the S/N ratio can be reduced. In addition, the visibility of the spot of the main light irradiated on the target object or the like can be improved.

In the aspect described above, the side surface is connected to the bottom surface and may have an angle of greater than 90 degrees with the bottom surface.

According to this aspect, the side surface is connected to the bottom surface, and forms an angle greater than 90 degrees with the bottom surface.

This allows the opening surface of the recessed portion to be enlarged, and more light emitted by the light source installed in the bottom surface to be emitted from the package.

In the aspect described above, the side surface may have a reflectance of 10% or less with respect to the light emitted from the light source.

According to this aspect, the side surface has a reflectance of 10% or less with respect to the light emitted from the light source. This can efficiently absorb the stray light emitted from the side surface, thereby reducing the possibility of false detection of the target object.

In the aspect described above, the side surface may be a rough surface.

According to this aspect, the side surface is a rough surface. This can cause the light to diffusely reflect on the side surface, thereby reducing the reflectance of the side surface.

In the aspect described above, the package may be formed of a material that absorbs the light emitted from the light source.

According to this aspect, the package is formed of a material that absorbs the light emitted from the light source. This stabilizes the stray light suppression characteristics and also facilitates the manufacturing of the package.

In the aspect described above, the package may be formed of a material that absorbs the light emitted from the light source, may have a metal electrode pattern on the bottom surface, and the light source may be connected to the metal electrode pattern.

According to this aspect, the package is formed of a material that absorbs the light emitted from the light source, has a metal electrode pattern on the surface of the bottom surface, and the light source is connected to the metal electrode pattern. Thus, when a light source having a lead frame of LED is used, various reflections may occur, resulting in problems with stray light. However, by forming the electrode as a wiring pattern made of metal on the bottom surface, even if the light from the light source hits the electrode, the occurrence of diffuse reflected light can be reduced because the pattern surface is a mirror surface and the incident angle is large, thereby reducing the generation of stray light.

In the aspect described above, the light projecting unit and the light receiving unit are provided in separate housings, the light projecting unit is configured to emit a light beam toward the outside, the light receiving unit is configured to receive light emitted from the light projecting unit, and the detection unit may be configured to detect the target object based on a change in amount of the received light.

According to this aspect, the light projecting unit and the light receiving unit are provided in separate housings, the light projecting unit emits a light beam toward the outside, the light receiving unit is configured to receive light emitted from the light projecting unit, and the detection unit detects the target object based on a change in amount of the received light. This can reduce false detection of the target object due to reception of the stray light itself or of the stray light reflected by an object other than the target object, for example, an equipment, and received.

In the aspect described above, the light projecting unit and the light receiving unit are provided in a common housing, the light projecting unit emits a light beam toward a retroreflective plate, the light receiving unit is disposed to receive light reflected by the retroreflective plate, and the detection unit may detect the target object based on a change in amount of the received light.

According to this aspect, the light projecting unit and the light receiving unit are provided in a common housing, the light projecting unit emits a light beam toward a retroreflective plate, the light receiving unit is disposed to receive light reflected by the retroreflective plate, and the detection unit detects the target object based on a change in amount of the received light. This can reduce the false detection of the target object due to the stray light being reflected by the target object and received, the decrease in the degree of installation freedom, and the decrease in the detection performance of the target object of the transparent body.

In the aspect described above, the light projecting unit and the light receiving unit are provided in a common housing, the light projecting unit emits the light beam toward the outside, the light receiving unit has a light receiving field and is disposed so as to be able to receive the reflected light from the region where the light beam intersects with the light receiving field, and the detection unit may detect the target object based on the change in amount of the received light.

According to this aspect, the light projecting unit and the light receiving unit are provided in a common housing, the light projecting unit emits the light beam toward the outside, the light receiving unit has a light receiving field and is disposed so as to be able to receive the reflected light from the region where the light beam intersects with the light receiving field, and the detection unit detects the target object based on the change in amount of the received light. Thus, expansion of the detection range due to stray light can be reduced to maintain the detection range, and false detections due to the stray light being reflected by an object other than the target object, for example, the equipment, and received, can be reduced.

In the aspect described above, the receiving axis of the light receiving unit and the projecting axis of the light projecting unit may be configured to intersect in a manner that the region where the light beam and the light receiving field intersect with each other is limited.

According to this aspect, the receiving axis of the light receiving unit and the projecting axis of the light projecting unit are configured to intersect in a manner that the region where the light beam and the light receiving field intersect with each other is limited. This solves the problem that it is difficult to achieve the area limitation when there is stray light.

In the aspect described above, the light projecting unit emits the light beam toward the outside, the light receiving unit is configured such that each of the plurality of pixels can detect the amount of the received light, and the received light amount distribution signal for each pixel is obtained for the received light, and the detection unit may detect the target object based on this obtained received light amount distribution signal.

According to this aspect, the light projecting unit emits the light beam toward the outside, the light receiving unit is configured such that each of the plurality of pixels can detect the amount of the received light, and the received light amount distribution signal for each pixel is obtained for the received light, and the detection unit detects the target object based on this obtained received light amount distribution signal. Thus, the stray light component in the received light amount distribution signal can be reduced and the fluctuation of the center of gravity in the received light amount distribution signal can be reduced, and thus false detection of the target object can be decreased.

According to the present disclosure, stray light can be reduced.

### BRIEF DESCRIPTION OF THE DRAWINGS

FIG. 1 is a block diagram illustrating a schematic configuration of an optical sensor in a first embodiment.

FIG. 2 is a diagram for describing the detection principle of the optical sensor in the first embodiment.

FIG. 3 is a cross-sectional view illustrating a schematic configuration around a light projecting unit of the optical sensor in the first embodiment.

FIG. 4 is an enlarged sectional-view of a main part illustrating a schematic configuration of the light projecting unit of the optical sensor in the first embodiment.

FIG. 5 is a diagram for describing a stray light path in a virtual light projecting unit.

FIG. 6 is an image illustrating a spot when an object is irradiated with light emitted from the light projecting unit of the optical sensor in the first embodiment.

FIG. 7 is a diagram for describing an example of the influence of stray light on a known optical sensor.

FIG. 8 is a diagram for describing another example of the influence of stray light on a known optical sensor.

FIG. 9 is a diagram for describing the detection principle when there is no target object of an optical sensor in a second embodiment.

FIG. 10 is a diagram for describing the detection principle when there is one target object of the optical sensor in the second embodiment.

FIG. 11 is a diagram for describing the detection principle when there is another target object of the optical sensor in the second embodiment.

FIG. 12 is a diagram for describing the influence of stray light when detecting one target object in a known optical sensor.

FIG. 13 is a diagram for describing the influence of stray light when detecting one target object in a known optical sensor.

FIG. 14 is a diagram for describing the influence of stray light when detecting another target object in a known optical sensor.

FIG. 15 is a diagram for describing the detection principle of an optical sensor in a third embodiment.

FIG. 16 is a diagram for describing the influence of stray light in a known optical sensor.

FIG. 17 is a diagram for describing the influence of stray light in a known optical sensor.

FIG. 18 is a diagram for describing the detection principle of an optical sensor in a fourth embodiment.

FIG. 19 is a diagram for describing the influence of stray light in a known optical sensor.

FIG. 20 is a block diagram illustrating the schematic configuration of an optical sensor in a fifth embodiment.

FIG. 21 is a diagram for describing the detection principle of the optical sensor according to the fifth embodiment.

FIG. 22 is a schematic diagram illustrating an application example of the optical sensor according to the fifth embodiment.

FIG. 23 is a waveform diagram illustrating an example of a received light amount distribution signal.

FIG. 24 is a waveform diagram for describing the effect of stray light in a known optical sensor.

### DETAILED DESCRIPTION

Embodiments of the present disclosure will be described below. In the following drawings, the same or similar parts are denoted by the same or similar reference signs. However, the drawings are schematic only. Thus, specific dimensions, or the like should be determined in light of the following description. It goes without saying that different drawings also include parts with dimensional relationships and proportions different from one another. In addition, interpretation of the technical scope of the present disclosure should not be limited to the embodiments.

### First Embodiment

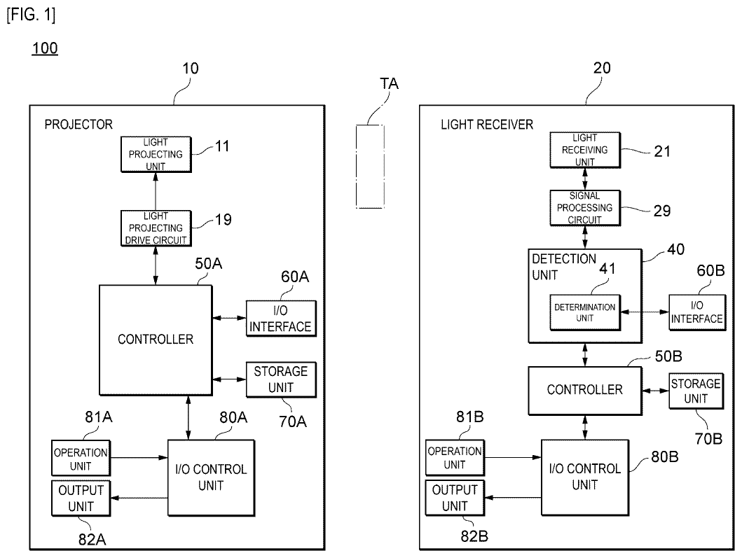

First, the configuration of an optical sensor according to a first embodiment will be described with reference to FIG. 1. FIG. 1 is a block diagram illustrating a schematic configuration of an optical sensor 100 in the first embodiment.

As illustrated in FIG. 1, the optical sensor 100 includes a projector 10 and a light receiver 20. The optical sensor 100 is, for example, a photoelectric sensor and is configured to detect a target object TA by utilizing various properties of light.

The optical sensor 100 of the present embodiment is a transmission-type photoelectric sensor, and the projector 10 and the light receiver 20 are housed in separate housings (cases) from each other.

The projector 10 includes a control unit 50A, an I/O interface (interface) 60A, a storage unit 70A, an I/O control unit 80A, an operation unit 81A, and an output unit 82A. The light receiver 20 includes a detection unit 40, a control unit 50B, an I/O interface 60B, a storage unit 70B, an I/O control unit 80B, an operation unit 81B, and an output unit 82B.

The detection unit 40 is configured to detect the target object TA based on the light received by a light receiving unit 21 described below. The detection unit 40 includes a processor. In this case, the processor of the detection unit 40 includes a program and data, for detecting the target object TA. Specifically, the detection unit 40 is configured to control the projector 10. The detection unit 40 generates control signals so as to control, for example, the intensity (power) of the light projected by the projector 10, the duration of projection, the period or interval of projection, and the timing of projection, or the like. The generated control signal is output to a signal processing circuit 29.

The detection unit 40 includes a determination unit 41 as a functional block. A received light amount signal, which indicates amount of light received by the light receiving unit 21, is input to the detection unit 40 via the signal processing circuit 29. Hereinafter, this “amount of light” is also referred to as “received light amount”. The detection unit 40 is configured to detect the target object TA based on the change in amount of the received light. In one example, the detection unit 40 outputs the detection signal and the amount of the received light to the outside via the I/O interface 60B. Note that details of the determination unit 41 will be described below.

The control unit 50A is configured to control the operation of each part of the projector 10, and the control unit 50B is configured to control the operation of each part of the light receiver 20. For example, the control unit 50B is connected to the detection unit 40 and exchanges signals and data with the detection unit 40. The control unit 50A includes a processor such as a CPU (Central Processing Unit), for example. The control unit 50B includes a processor such as an ASIC (Application Specific Integrated Circuit), for example.

An I/O interface 60A is an interface between the projector 10 and external devices, and an I/O interface 60B is an interface between the light receiver 20 and external devices. The I/O interfaces 60A and 60B are each configured to exchange data and signals with external devices. The I/O interfaces 60A and 60B are each configured to control communication with external devices.

The storage units 70A and 70B are configured to store programs, data, or the like. Specifically, the storage unit 70A stores data such as programs executed by the control unit 50A, setting items, setting contents, and set values, and the storage unit 70B stores data such as programs executed by the control unit 50B, setting items, setting contents, and set values. The storage units 70A and 70B are each configured to include memories such as ROM (Read Only Memory), RAM (Random Access Memory), and flash memory.

The I/O control unit 80A is configured to control the operation of the output unit 82A, and the I/O control unit 80B is configured to control the operation of the output unit 82B. The I/O control unit 80A is connected to the operation unit 81A and the output unit 82A, and the I/O control unit 80B is connected to the operation unit 81B and the output unit 82B. The I/O control unit 80A is connected to the control unit 50A and exchanges data with the control unit 50A, and the I/O control unit 80B is connected to the control unit 50B and exchanges data with the control unit 50B. Each of the I/O control units 80A and 80B includes, for example, a processor such as a CPU.

In the example illustrated in FIG. 1, the configuration, in which the control unit 50A and the I/O control unit 80A are independent elements, has been illustrated, but is not limited thereto. For example, the control unit 50A and the 1/O control unit 80A may be integrated. In this case, the control unit 50A and the I/O control unit 80A include, for example, a processor such as a CPU. Similarly, the configuration, in which the detection unit 40, the control unit 50B, and the 1/O control unit 80B are independent elements, has been illustrated, but is not limited thereto. For example, at least 2 of the detection unit 40, the control unit 50B, and an I/O control unit 80B may be integrally configured. The detection unit 40, the control unit 50B, and the I/O control unit 80B, when integrally configured, include, for example, a processor such as an ASIC.

The operation unit 81A is for inputting information to the projector 10, and the operation unit 81B is for inputting information to the light receiver 20. The operation units 81A and 81B each include, for example, buttons, switches, touch panels, and keyboards, or the like. For example, when a user operates at least one of the buttons, switches, touch panels, and keyboards, or the like, the I/O control units 80A or 80B generate data corresponding to the operation. In this way, information is input to the projector 10 and the light receiver 20.

The output units 82A and 82B are both for outputting information. Each of the output units 82A and 82B includes, for example, a display device, a pilot lamp, and a speaker. The pilot lamp includes, for example, a pilot lamp with one light emission diode (LED) and a 7-segment LED. In this case, a surface-emitting LED is used as the light emitting element. The display device includes, for example, a display panel such as a liquid crystal display, an electroluminescence (EL) display, a plasma display, an organic electro-luminescence (OLED) display, a quantum dot organic EL (QD-OLED) display, a mini-LED display, and a micro-LED display. The output units 82A and 82B drive at least one of the display device, the pilot lamp, and the speaker to output information based on a control signal input from the I/O control units 80A and 80B, respectively.

In the present embodiment, an example in which an ASIC or a CPU is used as a processor has been illustrated, but is not limited thereto. The processor of the optical sensor 100 may employ an integrated circuit such as a digital signal processor (DSP), a field-programmable gate array (FPGA), a programmable logic device (PLD), or a system-on-a-chip (SoC), for example, in place of or in addition to ASIC or CPU.

The projector 10 further includes a light projecting unit 11 and a light projecting drive circuit 19. The light projecting unit 11 is configured to emit light from, for example, a light projecting window (not illustrated) formed in the housing. The light projecting drive circuit 19 is for driving the light projecting unit 11. Specifically, the light projecting drive circuit 19 outputs a drive signal to the light projecting unit 11 based on a control signal input from the control unit 50A.

The light projecting unit 11 is driven by the drive signal and emits light.

The light receiver 20 further includes the light receiving unit 21 and the signal processing circuit 29. The light receiving unit 21 is configured to receive light incident from, for example, a light receiving window (not illustrated) formed in the housing. More specifically, the light receiving unit 21 is configured to receive light emitted from the light projecting unit 11. The light receiving unit 21 is configured to include, for example, one or more light-receiving elements. The light-receiving element is, for example, a photo-diode (PD). The light receiving unit 21 may further include, in addition to the light-receiving element, a condenser lens, a filter, or the like. The light-receiving element outputs an electric signal corresponding to the amount of the received light received during a predetermined exposure time. When a PD is used as the light-receiving element, a charge storage unit which accumulates electric charges according to the amount of the received light received during the exposure time, may be provided externally.

The signal processing circuit 29 controls light reception by the light receiving unit 21. For example, the signal processing circuit 29 outputs a control signal to the light receiving unit 21 so that the light-receiving element receives light during the exposure time and outputs an electric signal during a period other than the exposure time, that is, during a non-exposure period.

This control signal is input from the detection unit 40.

An electric signal is input to the signal processing circuit 29 from the light-receiving element of the light receiving unit 21. The signal processing circuit 29 includes an amplifier circuit (not illustrated), which amplifies the input electric signal with a predetermined gain and outputs the amplified signal. When the electric signal of the light receiving unit 21 is a current signal, the signal processing circuit 29 may include a current/voltage conversion circuit. In this case, the signal processing circuit 29 converts the input current signal into a voltage value corresponding to the current value. Then, the signal processing circuit 29 amplifies the converted voltage signal by an amplifier circuit and outputs the amplified signal. This amplified signal is output to the detection unit 40 as a signal indicating the amount of the received light.

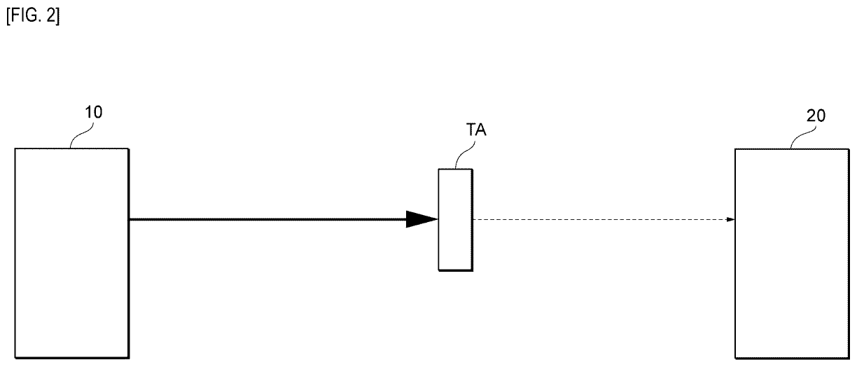

The detection principle of the optical sensor according to the first embodiment will now be described. FIG. 2 is a view for illustrating the detection principle of the optical sensor 100 according to the first embodiment.

As illustrated in FIG. 2, the projector 10 and the light receiver 20 are arranged so that the light emitted from the projector 10 enters the light receiver 20. More specifically, the projector 10 and the light receiver 20 are arranged so that the projection window of the projector 10 faces the light receiving window of the light receiver 20. When the target object TA exists in the space between the projector 10 and the light receiver 20, the target object TA blocks or attenuates the light emitted from the projector 10, and the amount of light incident on the light receiver 20 decreases. Based on the change in amount of the received light received by the light receiving unit 21 of the light receiver 20, the detection unit 40 illustrated in FIG. 1 is configured to detect the target object TA and generate a detection signal for the target object TA.

Specifically, the determination unit 41 of the detection unit 40 illustrated in FIG. 1 compares the value of the amount of the received light received by the light receiver 20 with the threshold for determination, and determines the presence or absence of the target object TA. While the amount of the received light is above the threshold, it is considered that there is no target object TA between the projector 10 and the light receiver 20. Thus, the detection unit 40 sets the signal level of the detection signal to a level indicating an off state, for example, a low level. On the other hand, when the amount of the received light is below the threshold, it is considered that there is the target object TA between the projector 10 and the light receiver 20, and the light from the projector 10 to the light receiver 20 is blocked or attenuated by the target object TA. Thus, the detection unit 40 sets the signal level of the detection signal to a level indicating an on state, for example, a high level. Thus, the detection unit 40 can detect the presence or absence of the target object TA.

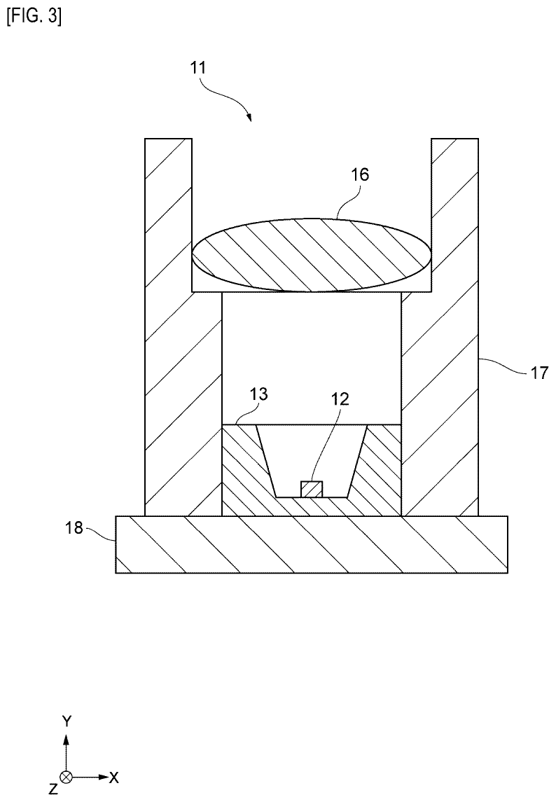

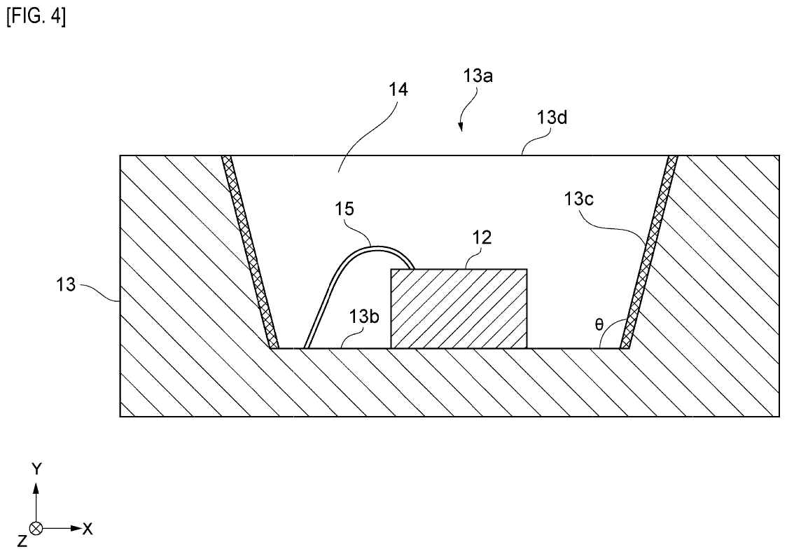

Next, the configuration of the light projecting unit of the optical sensor according to the first embodiment will be described with reference to FIGS. 3 and 4. FIG. 3 is a cross-sectional view illustrating a schematic configuration around the light projecting unit 11 of the optical sensor 100 in the first embodiment. FIG. 4 is an enlarged cross-sectional view illustrating a schematic configuration of a package 13 of the optical sensor 100 in the first embodiment.

The light projecting unit 11 is housed in a housing of the projector 10.

The light projecting unit 11 emits a light beam toward the outside. As illustrated in FIG. 3, the housing of the projector 10 further includes a lens holder 17 and a substrate 18 in addition to the light projecting unit 11.

The light projecting unit 11 includes a light source 12, the package 13, and a light projecting lens 16. The light source 12 is configured to emit light. The light source 12 includes a light emitting element such as an LED or a laser diode.

A wide variety of light sources 12 can be used regardless of the type of light emitted. For example, a point light source or a surface-emitting LED may be used as the light source 12. In addition, a laser diode emitting a VCSEL (Vertical Cavity Surface Emitting Laser) may be used.

In the package 13, a recessed portion 13a such as a cavity and a recess is formed on one surface (upper surface in FIGS. 3 and 4). The material of the package 13 may be epoxy resin, and ceramic such as aluminum oxide (Al₂O₃), aluminum nitride (AlN). The package 13 is formed together with the recessed portion 13a by using, for example, a mold.

As illustrated in FIG. 4, the recessed portion 13a includes an opening 13d which is opened toward the light projection direction of the projector 10, for example, the positive direction of the Y-axis in FIGS. 3 and 4. The recessed portion 13a further includes a bottom surface 13b on which the light source 12 is installed. The light source 12 is installed so that the light emitting surface (upper surface in FIGS. 3 and 4) emitting the primary light (hereinafter also referred to as “main light”) faces the opening 13d side.

The light projecting unit 11 further includes a resin 14 covering the light source 12. The resin 14 is light transmissive to the light of the light source 12. The material of the resin 14 is, for example, epoxy resin or silicone resin. The resin 14 is filled in the recessed portion 13a after the light source 12 is installed on the bottom surface 13b.

Thus, the light projecting unit 11 further includes the resin 14, which is light transmissive and covers the light source 12. Thus, the light source 12 can be protected and fixed to the bottom surface 13b of the recessed portion 13a.

The recessed portion 13a further includes a side surface 13c connecting the bottom surface 13b and the opening 13d. The side surface 13c forms an angle θ with the bottom surface 13b. The recessed portion 13a is formed so that the area of the bottom surface 13b is smaller than the area of the surface, which is hereinafter also referred to as “opening surface”, including the opening 13d. Thus, the side surface 13c is inclined, and this angle θ is greater than 90 degrees and less than 180 degrees (180°>θ>90°). This allows the opening surface of the recessed portion 13a to be enlarged, and more light emitted by the light source 12 installed in the bottom surface 13b to be emitted from the package 13.

The light projecting unit 11 further includes a bonding wire 15 connected to the light source 12. The bonding wire 15 is, for example, a wire made of gold (Au), and electrically connects the light source 12 and the substrate 18.

The light projecting lens 16 is configured to condense the light of the light source 12. Specifically, the light projecting lens 16 is installed at a position separated from the package 13 by a predetermined distance. More specifically, the light projecting lens 16 is positioned on one side (in the positive Y-axis direction in FIG. 3) of the package 13 so that light emitted from the opening 13d of the recessed portion 13a enters the lens. The light projecting lens 16 is fixed and held by the lens holder 17.

The light projecting lens 16 is, for example, a convex lens. In this case, the light projecting lens 16 refracts the light flux incident on one surface (the lower surface in FIG. 3) and emits the light flux from the other surface (the upper surface in FIG. 3) so that the refracted light flux concentrates on a predetermined focus.

In this way, the optical sensor 100 further includes the light projecting lens 16, which is disposed relative to the package 13 so as to receive the incident light emitted from the opening 13d of the recessed portion 13a. As a result, the light emitted from the package 13 can be refracted, diverged, or focused, thereby easily irradiating the target object TA, the light receiving unit 21, or the like.

In the present embodiment, an example in which the light projecting lens 16 is one is illustrated, but is not limited thereto. The optical sensor 100 may include two or more light projecting lenses. In addition, the optical sensor 100 may include other lenses, or other optical members such as mirrors, in place of or together with the light projecting lens.

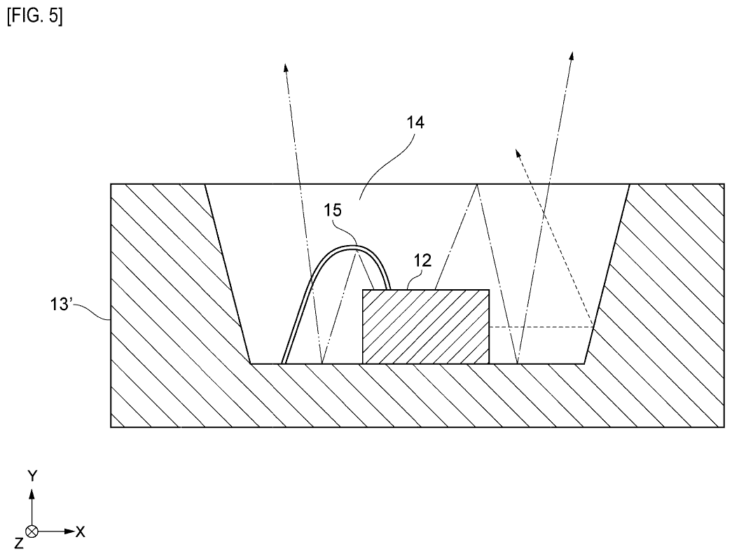

The generation of stray light will now be described. FIG. 5 is a diagram for describing a stray light path in the virtual light projecting unit. Note that this virtual light projecting unit is provided by a known optical sensor, and the same or similar configuration as the light projecting unit 11 of the present embodiment is denoted by the same or similar reference numerals, and the description thereof will be omitted appropriately. FIG. 5 is a diagram corresponding to the enlarged sectional view of the main part of the package 13 illustrated in FIG. 4.

As illustrated in FIG. 5, the light source 12 is installed on the bottom surface of the recessed portion (not illustrated) formed in the package 13′ and is covered with resin 14. The bonding wire 15 is connected to the light source 12.

Examples of stray light generated in the virtual light projecting unit are as follows. As illustrated by a broken line in FIG. 5, the light emitted from the side surface of the light source 12 is reflected by the side surface of the recessed portion formed in the package 13′, and stray light is generated that follows a path that leads to a light projecting lens (not illustrated). As illustrated by one dot chain line in FIG. 5, a stray light is generated that follows a path, in which the light emitted from the top surface of the light source 12 is reflected by the surface of the resin 14, and further reflected by the bottom surface of the recessed portion formed in the package 13′ and enters the light projecting lens. Furthermore, as illustrated by a two dot chain line in FIG. 5, a stray light is generated that follows a path, in which the light emitted from the top surface of the light source 12 is reflected by the bonding wire 15, and further reflected by the bottom surface of the recessed portion formed in the package 13′ and enters the light projecting lens.

As a result of analyzing the stray light in the virtual light projecting unit using optical simulation, the inventors of the present disclosure found that the stray light in the generation path illustrated by a broken line in FIG. 5 was the main factor among the stray lights following such various generation paths. Then, it was achieved that the influence of the stray light can be greatly eliminated by applying a means for reducing the amount of this stray light.

On the other hand, the side surface 13c of the recessed portion 13a formed in the package 13 of the present embodiment illustrated in FIG. 4 contains a material which absorbs the light emitted by the light source 12. Specifically, the side surface 13c is composed of a material having black color. For example, the side surface 13c is composed of a black epoxy resin. Alternatively, the side surface 13c is a powder such as alumina coated with a black pigment and sintered. It is preferable that all the side surfaces 13c surrounding the light source 12 include a material that absorbs light from the light source 12. In addition, not only the side surface 13c but also the entire package 13 may be formed of a material that absorbs light from the light source 12.

Here, for comparison, the light amount and reflectance of the virtual light projecting unit illustrated in FIG. 5 will be described. In the virtual light projecting unit, by using a white package 13′ with relatively high reflectance, the irradiating light emitted to the target object, for example, the screen, the light amount of stray light relative to the amount of main light was 153%, and this means that the light amount of stray light is 1.5 times or more than that of the main light. At this time, the reflectance of the package 13′ for a wavelength band 610 nm to 980 nm of the light source 12 was about 90%.

The reflectance (=numerator/denominator) here is defined as follows. “Denominator” is defined as the total light amount that directly enters the side surface 13c of the package 13, among the light emitted from the light source 12. However, here, light is excluded which enters the side surface 13c after being reflected by other paths.

“Numerator” is defined as the total light amount that reflects near the interface of the side surface 13c and directly passes through the opening 13d, among the light that has entered the side surface 13c described above. However, here, light is excluded which directly passes the opening 13d through the other path.

On the other hand, in the package 13 of the present embodiment illustrated in FIG. 4, when the package 13, which is entirely black including the side surface 13c, is used, the irradiating light irradiated on the target object, for example, the screen, has the light amount 0.03% of the stray light relative to that of the main light, and it can be said that almost no stray light exists. At this time, the reflectance of the package 13 for the wavelength band 610 nm to 980 nm of the light source 12, was about 4%.

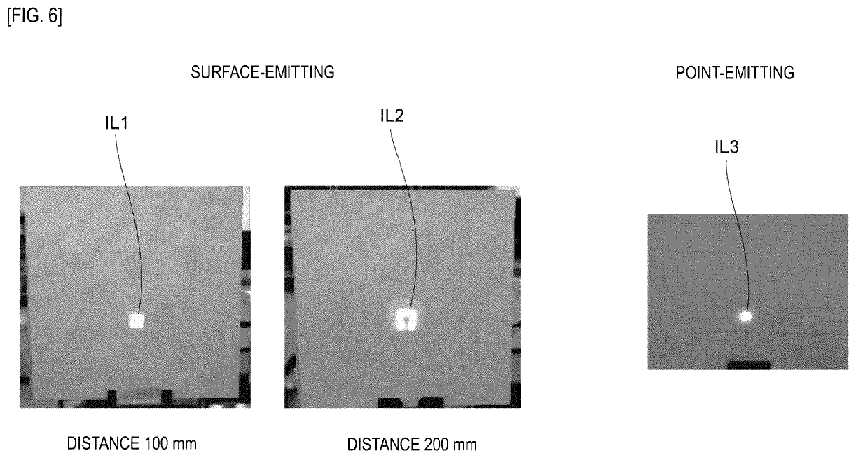

Next, referring to FIG. 6, irradiating light of the light projecting unit of the optical sensor according to the first embodiment, will be described. FIG. 6 is an image illustrating a spot when an object is irradiated with light emitted from the light projecting unit 11 of the optical sensor 100 in the first embodiment. In the image illustrated in FIG. 6, a graph paper is placed at a position separated by a predetermined distance from the projector 10, and the light irradiated on the graph paper is photographed.

As illustrated in FIG. 6, when a surface-emitting type LED is used as the light source 12, it was confirmed that irradiated light IL1 on the graph paper at a distance of 100 mm from the projector 10 has significantly reduced stray light and has achieved a high ratio of the light amount of the main light. Similarly, it was confirmed that irradiated light IL2 on the graph paper at a distance of 200 mm from the projector 10 has significantly reduced stray light and has maintained a high ratio of the light amount of the main light. Even when a point-emitting type LED is used as the light source 12, it was confirmed that irradiated light IL3 has significantly reduced stray light and has achieved a high ratio of the light amount of the main light.

As described above, in the optical sensor 100, the light projecting unit 11 further includes the package 13 in which the light source 12 is installed on the bottom surface 13b of the recessed portion 13a, and the resin 14 that is light transmissive and covers the light source 12, and the side surface 13c of the recessed portion 13a includes a material that absorbs light from the light source 12. As a result, the light emitted from the light source 12 installed on the bottom surface 13b and incident on the side surface 13c is absorbed, making it possible to reduce stray light that passes through the side surface 13c, which is the main factor in stray light generation. Therefore, stray light can be reduced, and a decrease in the S/N ratio can be reduced. In addition, the visibility of the spot of the main light irradiated on the target object TA or the like can be improved.

Preferably, the reflectance of the side surface 13c to the light emitted from the light source 12 is greater than 0% and 10% or less. In general, among the target objects detected by the photoelectric sensor, when black paper is assumed as the target object having relatively the lowest reflectance in practical use, its reflectivity is 6%. On the other hand, when a metallic object such as aluminum (Al) is assumed as the target object having a relatively high reflectance, its reflectance is 60% or more. In addition, when an LED is used as the light source, if considering that light amount emitted from the front surface and side surface of the LED is considered to be almost the same, then, once the light emitted from the front surface is irradiated on the black paper at the center of the spot and the light emitted from the side surface is reflected by the metallic object existing around the spot, the target object can be detected by mistake due to the ambient light or not detected by mistake (hereinafter, both are collectively referred to as “false detection”), which are thereby necessary to be avoided. Thus, it is desirable that the side surface of the package, which the light from the side surface of the LED enters, has a reflectance of 10% or less.

Thus, the reflectance of the side surface 13c with respect to the light emitted from the light source 12 is 10% or less. This can efficiently absorb the stray light originated from the side surface 13c, thereby reducing the possibility of false detection of the target object TA.

Further, it is more preferable that the reflectance of the side surface 13c with respect to the light emitted from the light source 12 is greater than 0% and 6% or less. In other words, when a high reflectance object such as a reflective film existing in the surroundings reflects at almost 100%, which is the theoretical maximum value, the target object may be falsely detected by ambient light. In this case, preferably the reflectance of the side surface of the package, which the light from the side surface of the LED enters, is 6% or less.

Thus, the reflectance of the side surface 13c with respect to the light emitted from the light source 12, is 6% or less. This can further efficiently absorb the stray light originated from the side surface 13c, thereby further reducing the possibility of false detection of the target object TA.

The side surface 13c may be a rough surface. In this case, the side surface 13c is formed by using a mold with a rough surface. Specifically, the surface roughness of the side surface 13c, such as arithmetic mean roughness (Ra), has a maximum value of 0.03 μm or more. Thus, by roughening the side surface 13c to cause diffuse reflection, the reflectance of the side surface 13c can be reduced as a result.

The flatness of the side surface 13c may be lower than that of the opening 13d (the interface of the resin 14). The opening 13d is usually manufactured flat. If the opening 13d has a rough surface, light scattering may occur there, which is undesirable.

The package 13 is formed of a material that absorbs light from the light source 12. This stabilizes the stray light suppression characteristics and also facilitates the manufacturing of the package 13.

In addition, the package 13 may have a metal electrode pattern on the surface of the bottom surface 13b, and the light source 12 may be connected to the metal electrode pattern. Thus, when a lead frame of LED is used as the light source 12, various reflections may occur, resulting in problems with stray light. However, by forming the electrode as a wiring pattern made of metal on the bottom surface 13b, even if the light from the light source 12 hits the electrode, the occurrence of diffuse reflected light can be reduced because the pattern surface is a mirror surface and the incident angle is large, thereby reducing the generation of stray light.

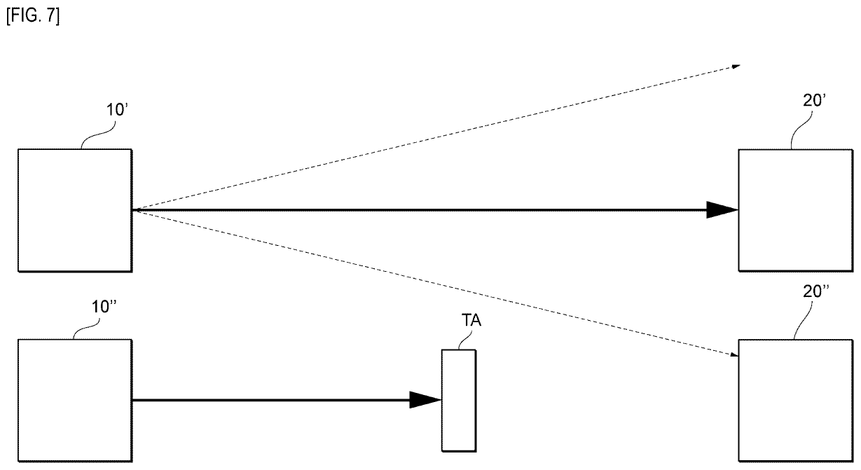

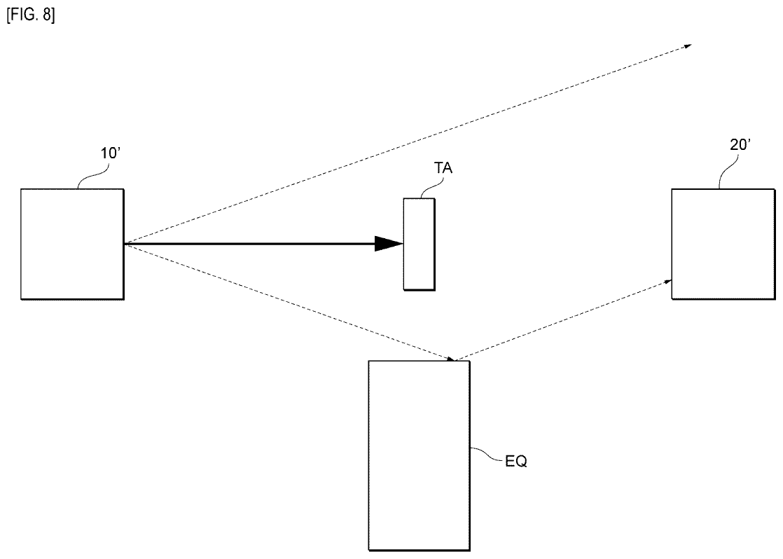

Next, the influence of stray light on a known optical sensor will be described with reference to FIGS. 7 and 8. FIG. 7 is a diagram for describing one example of the influence of stray light in a known optical sensor. FIG. 8 is a diagram for describing another example of the influence of stray light in a known optical sensor. Note that each of the known optical sensors in FIGS. 7 and 8 is a transmission-type photoelectric sensor, and only the projector and light receiver provided in the known optical sensor are illustrated for simplicity of explanation.

As illustrated in FIG. 7, when multiple optical sensors are arranged adjacent to each other at a close distance, once the light emitted from the projector 10′ includes stray light indicated by a broken line, the stray light may enter the light receiver 20″ of the adjacent optical sensor. In this case, under normal conditions, the target object TA is configured to block the light emitted from the projector 10″, thereby detected. However, if the stray light enters the light receiver 20″ and is received, it may be falsely determined that the target object TA is not present.

Furthermore, as illustrated in FIG. 8, when an equipment EQ is located near the optical sensor, once the light emitted from the projector 10′ includes stray light indicated by a broken line, the stray light may be reflected by the equipment EQ, and the reflected light may enter the light receiver 20′. In this case, the light emitted from the projector 10′ is blocked by the target object TA located between the projector 10′ and the light receiver 20′, and the target object TA is configured to be detected due to decreasing of the amount of the received light, however, the reflected light reflected by the equipment EQ enters the light receiver 20′ and is received. As a result, the amount of the received light does not decrease significantly, and it may be falsely determined that there is no target object TA.

On the other hand, in the optical sensor 100 of the present embodiment, the light projecting unit 11 and the light receiving unit 21 are set as separate housings. The light projecting unit 11 emits a light beam toward the outside, the light receiving unit 21 is set so as to be able to receive the light emitted from the light projecting unit 11, and the detection unit 40 detects the target object TA based on the change in amount of the received light. This can reduce false detection of the target object TA due to reception of the stray light itself or of the stray light that is reflected by an object other than the target object, for example, the equipment EQ, and received.

### Second Embodiment

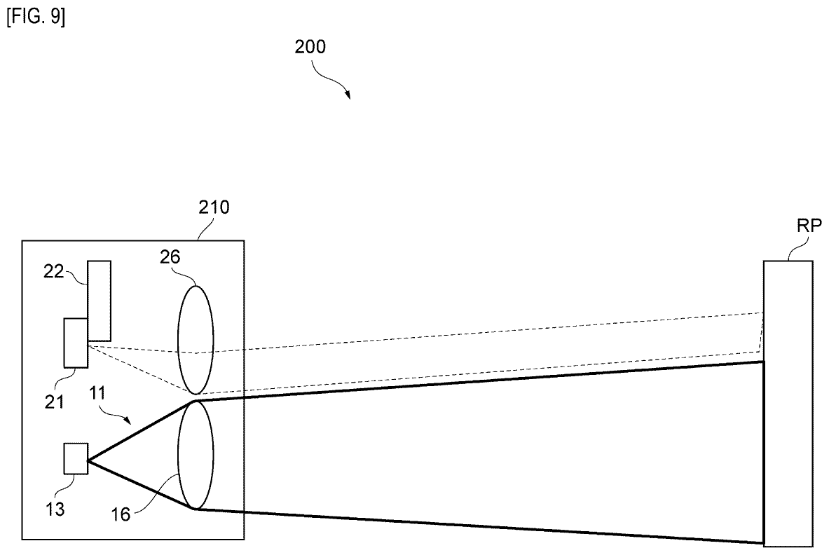

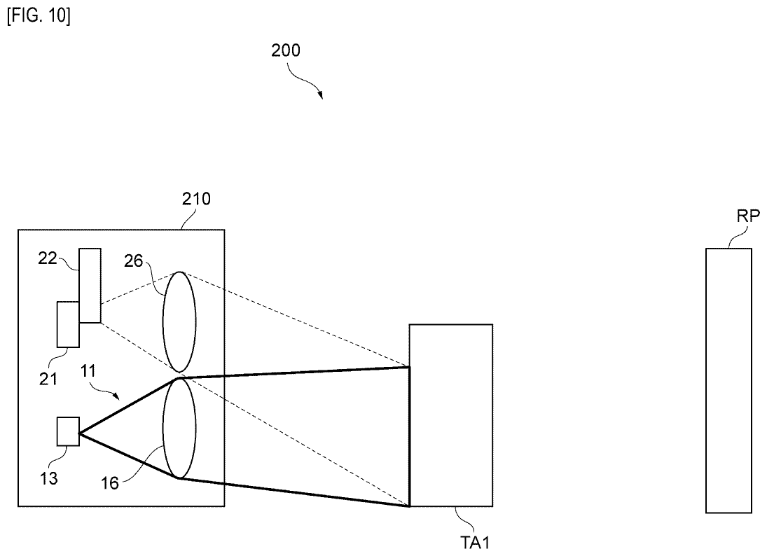

Next, the detection principle of the optical sensor according to a second embodiment will be described with reference to FIGS. 9 to 11. FIG. 9 is a diagram for describing the detection principle of an optical sensor 200 according to the second embodiment when there is no target object. FIG. 10 is a diagram for illustrating the detection principle of the optical sensor 200 according to the second embodiment when there is one target object TA1.

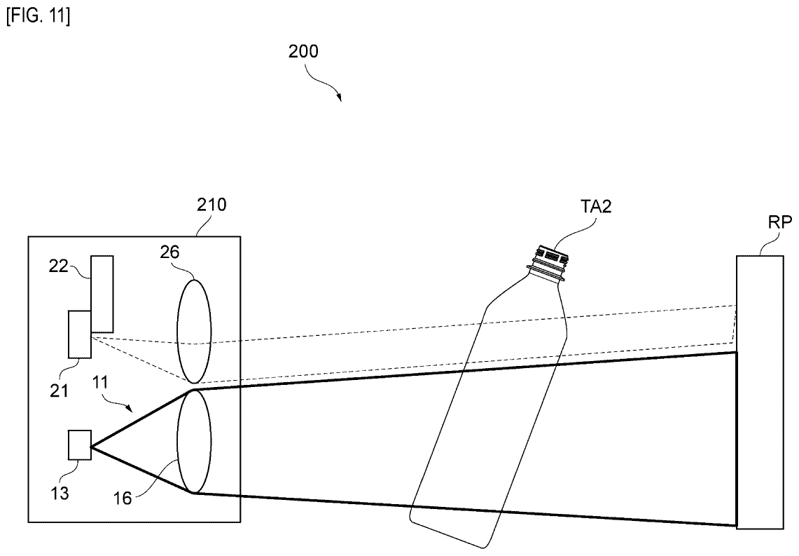

FIG. 11 is a diagram for describing the detection principle of the optical sensor 200 according to the second embodiment when there is another target object TA2. In the second embodiment, the same or similar components as in the first embodiment are denoted by the same or similar reference numerals, and the description thereof is omitted as appropriate, except where specifically indicated. In addition, the differences from the first embodiment will be mainly described below, and similar functions and effects of the same components as in the first embodiment will not be mentioned successively.

The optical sensor 200 according to the present embodiment is a retroreflective photoelectric sensor. As illustrated in FIG. 9, the light projecting unit 11 and the light receiving unit 21 are housed in the same housing, defined as a light projector and receiver 210. The light projector and receiver 210 are arranged to face a retroreflective plate RP. The retroreflective plate RP may be, for example, a resin molded product or a sheet, or the like. The light projecting unit 11 emits a light beam toward the retroreflective plate RP through the light projecting lens 16 from the package 13 in which the light source 12 is installed on the bottom surface 13b. The irradiated light is reflected by the retroreflective plate RP and returned to the light projector and receiver 210. The reflected light is received by the light receiving unit 21 through a light receiving lens 26.

As illustrated in FIG. 10, when the target object TA1 exists in the space between the light projector and receiver 210 and the retroreflective plate RP, the light beam emitted from the light projecting unit 11 is blocked by the target object TA1. The light reflected by the target object TA is not incident on the light receiving unit 21. More specifically, the light receiving unit 21 is provided with a blocking member 22 such as a slit, for example, and the light reflected at a position before the retroreflective plate RP is designed to be incident on the blocking member 22.

Thus, the amount of reflected light received by the light receiving unit 21 decreases, and as in the first embodiment, the detection unit 40 is configured to detect the target object TA1 and generate a detection signal for the target object TA1 based on the change in the received amount of reflected light.

In addition, as illustrated in FIG. 11, when the transparent target object TA2 exists in the space between the light projector and receiver 210 and the retroreflective plate RP, a part of the light beam emitted from the light projecting unit 11 can pass through the target object TA2 and be reflected by the retroreflective plate RP, and the reflected light can pass through the target object TA2 again and be incident on the light receiving unit 21. At this time, a part of the light incident on the surface of the target object TA2 is refracted, and this refracted light is not incident on the light receiving unit 21, so that the amount of reflected light received by the light receiving unit 21 decreases. As in the first embodiment, the detection unit 40 is configured to detect the target object TA2 and generate a detection signal of the target object TA2 based on the change in the amount of reflected light received.

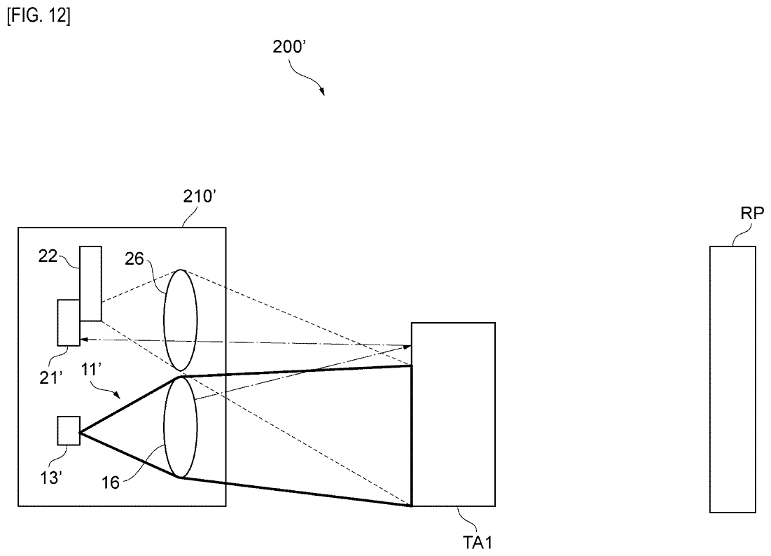

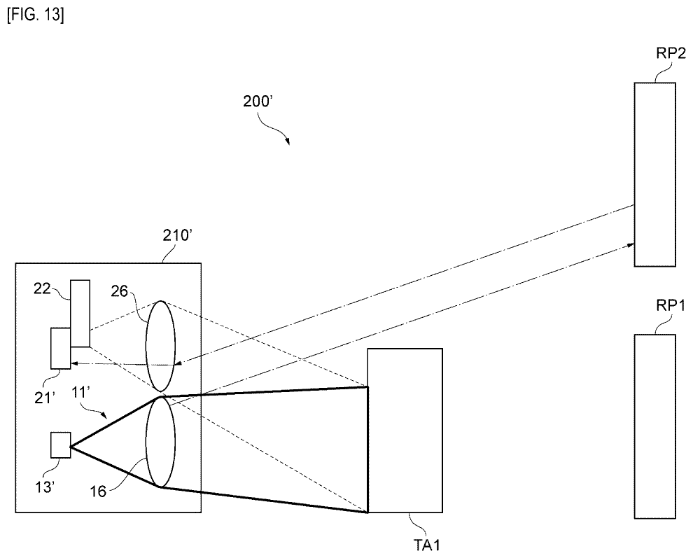

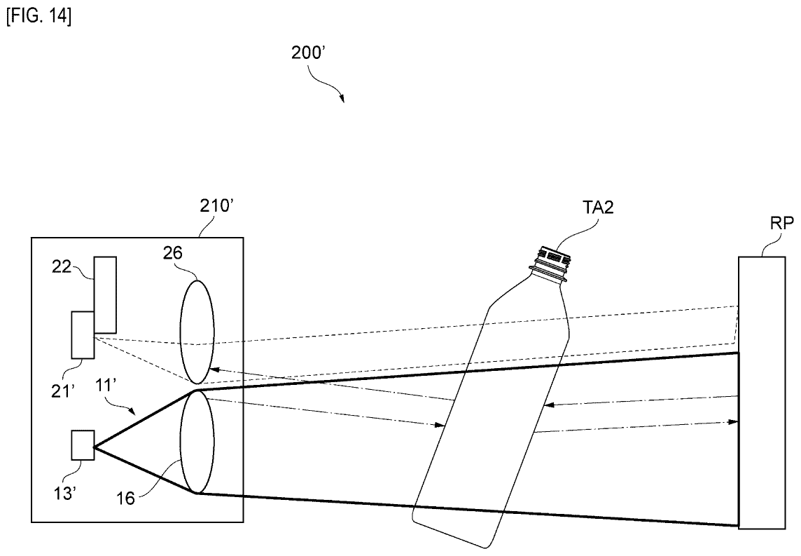

Next, the influence of stray light in a known optical sensor will be described with reference to FIGS. 12 to 14. FIG. 12 is a diagram for describing the influence of stray light when detecting one target object TA1 in the known optical sensor 200′. FIG. 13 is a diagram for illustrating the influence of stray light when detecting one target object TA1 in a known optical sensor 200′. FIG. 14 is a diagram for describing the influence of stray light when detecting another target object TA2 in the known optical sensor 200′. Note that each of the known optical sensor 200′ in FIGS. 12 to 14 is a retroreflective photoelectric sensor, and only the light projector and receiver 210′ of the known optical sensor is illustrated for simplicity of description.

As illustrated in FIG. 12, if the light emitted from the package 13′ and the light projecting lens 16 in the light projecting unit 11′ includes stray light indicated by one dot chain line, when the target object TA1 is blank, or the like, the stray light is diffusely reflected by the target object TA1, and is likely to enter the light receiving unit 21′ and be received. In this case, under normal conditions, the light emitted from the light projecting unit 11′ is reflected by the target object TA1, and this reflected light is blocked by the blocking member 22, thereby configured to detect the target object TA1. However, if the stray light enters the light receiving unit 21′ and is received, it may be determined that there is no target object TA1.

In addition, as illustrated in FIG. 13, if a plurality of retroreflective plates RP1 and RP2 are arranged adjacent to each other at a close distance, and if the light emitted from the light projecting unit 11′ includes stray light indicated by one dot chain line, the stray light may be reflected by the adjacent retroreflective plate RP2, and is likely to enter the light receiving unit 21′ and be received. In this case, under normal conditions, the light emitted from the light projecting unit 11′ is reflected by the target object TA1, and this reflected light is blocked by the blocking member 22, thereby configured to detect the target object TA1.

However, since the reflected light reflected by the retroreflective plate RP2 enters the light receiving unit 21′ and is received, this can cause false determination that there is no target object TA1. Thus, the degree of installation freedom of the known optical sensor 200′ becomes low.

Furthermore, as illustrated in FIG. 14, when the target object TA2 is a transparent body, if the light emitted from the light projecting unit 11′ contains stray light indicated by one dot chain line, the stray light may be refracted by the target object TA2 and reflected by the retroreflective plate RP. Then the reflected light may be refracted by the target object TA2 again and incident on the light receiving unit 21′. In this case, the light emitted from the light projecting unit 11′ is attenuated by the target object TA2, which is thus configured to be detected due to decreased amount of the received light. However, the reflected light of the stray light refracted by the target object TA2 enters the light receiving unit 21′ and is received. As a result, the decrease in the amount of the received light is reduced, or rather, the amount of the received light increases, and it can be falsely determined that the target object TA2 is not present. Therefore, the known optical sensor 200′ has a low detection performance of the target object TA2 of the transparent body.

On the other hand, in the optical sensor 200 of the present embodiment, the light projecting unit 11 and the light receiving unit 21 are provided in a common housing, the light projecting unit 11 emits the light beam toward the retroreflective plate RP, the light receiving unit 21 is disposed so as to be able to receive the light reflected by the retroreflective plate RP, and the detection unit 40 detects the target objects TA1 and TA2 based on the change in amount of the received light. This can reduce the false detection of the target object TA1 due to the stray light being reflected by the target object TA1 and received, the decrease in the degree of installation freedom, and the decrease in the detection performance of the target object TA2 of the transparent body.

### Third Embodiment

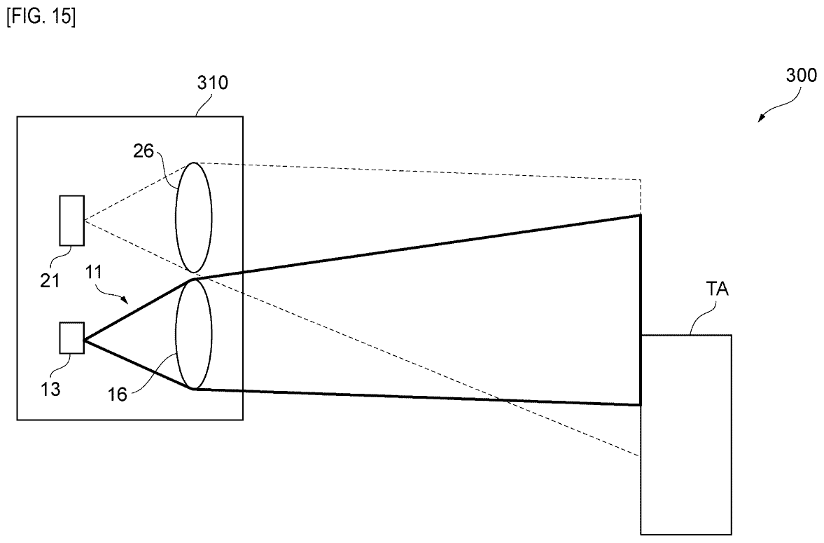

Next, the detection principle of the optical sensor according to a third embodiment will be described with reference to FIG. 15. FIG. 15 is a diagram for describing the detection principle of an optical sensor 300 according to the third embodiment. In the third embodiment, the same or similar components as in the embodiments described above are denoted by the same or similar reference numerals, and the description thereof is omitted as appropriate, except where specifically indicated. In addition, the differences from the embodiments described above will be mainly described below, and similar functions and effects of the same components as in the embodiments described above will not be mentioned each time.

The optical sensor 300 according to the present embodiment is a diffuse reflection type photoelectric sensor. As illustrated in FIG. 15, the light projecting unit 11 and the light receiving unit 21 are housed in the same housing, as a light projector and receiver 310. The light projecting unit 11 emits a light beam toward the outside. The light receiving unit 21 has a light receiving field and is disposed so as to receive reflected light from the region where the light beam intersects with the light receiving field. When there is no target object TA, in the light projecting unit 11, the light beam emitted from the package 13, in which the light source 12 is installed on the bottom surface 13b, through the light projecting lens 16, is not reflected and does not return to the light projector and receiver 310. On the other hand, as illustrated in FIG. 15, when there is the target object TA in the area where the spot of the light beam emitted from the light projecting unit 11 overlaps with the light receiving field of the light receiving unit 21, the emitted light is reflected by the target object TA and returns to the light projector and receiver 310. This reflected light is received by the light receiving unit 21 through the light receiving lens 26. Thus, the light amount received by the light receiving unit 21 increases compared to when there is no target object TA. The detection unit 40 is configured to detect the target object TA and generate a detection signal for the target object TA based on the change in the amount of reflected light received.

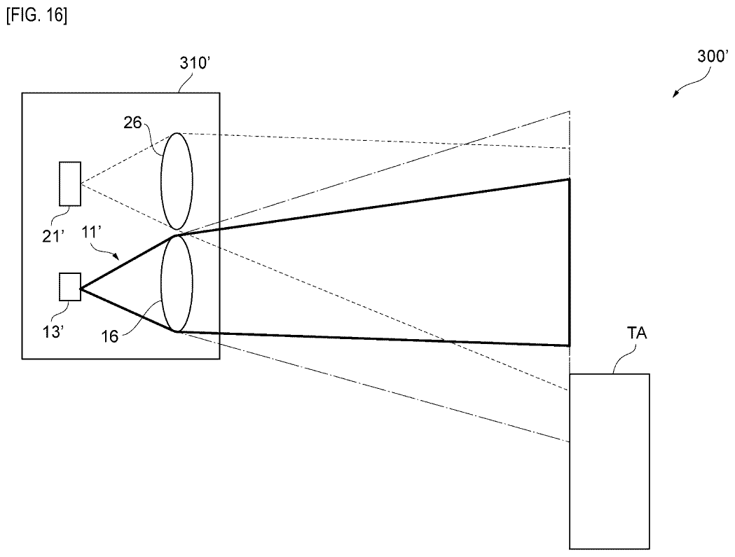

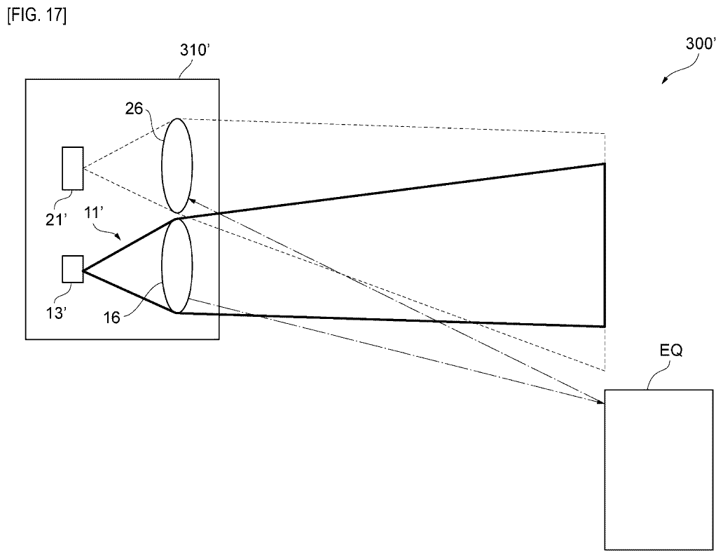

Next, the effect of stray light in the known optical sensor will be described with reference to FIGS. 16 and 17. FIG. 16 is a diagram for describing the effect of stray light in a known optical sensor 300′. FIG. 17 is a diagram for describing the effect of stray light in the known optical sensor 300′.

Note that the known optical sensor 300′ in FIGS. 16 and 17 is a diffuse reflection type photoelectric sensor, and only the light projector and receiver 310′ of the known optical sensor 300′ is illustrated for simplicity of description.

As illustrated in FIG. 16, if the light emitted from the package 13′ and the light projecting lens 16 in the light projecting unit 11′ includes stray light indicated by one dot chain line, the portion overlapping the light receiving field, that is, the detection range, expands. Thus, under normal conditions, the light emitted from the light projecting unit 11′ is irradiated to an object such as the target object TA that is located in the light receiving field but does not overlap the light projecting spot. In applications where the spot of the light emitted from the light projecting unit 11′ is to be limited, the detection range is to be controlled, but since stray light is not intended in the design, it becomes difficult to maintain the detection range of light including stray light.

In addition, as illustrated in FIG. 17, in an environment where an object with a high reflectance such as the equipment EQ exists, when the light emitted from the light projecting unit 11′ includes stray light indicated by one dot chain line, the stray light may be reflected by the equipment EQ and incident to and received by the light receiving unit 21′. In this case, under normal conditions, the reflected light is configured not to be received because the target object TA does not exist, but if the reflected light reflected by the equipment EQ is incident to and received by the light receiving unit 21′, which may cause false detection that the target object TA exists.

On the other hand, in the optical sensor 300 of the present embodiment, the light projecting unit 11 and the light receiving unit 21 are provided in a common housing, the light projecting unit 11 emits the light beam toward the outside, the light receiving unit 21 has a light receiving field and is disposed so as to be able to receive the reflected light from the region where the light beam intersects with the light receiving field, and the detection unit 40 detects the target object TA based on the change in amount of the received light. Thus, expansion of the detection range due to stray light can be reduced to maintain the detection range, and false detections due to the stray light being reflected and received by an object other than the target object, for example, the equipment EQ, can be reduced.

### Fourth Embodiment

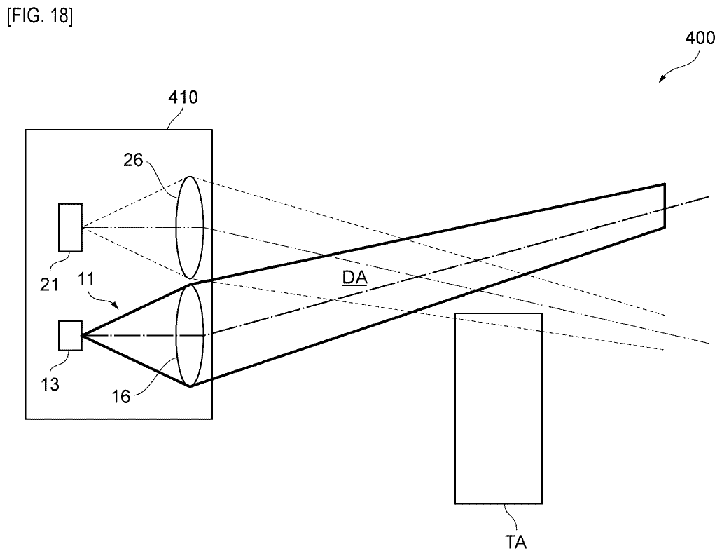

Next, the detection principle of the optical sensor according to a fourth embodiment will be described with reference to FIG. 18. FIG. 18 is a diagram for describing the detection principle of an optical sensor 400 according to the fourth embodiment. In the fourth embodiment, the same or similar components as in the embodiments described above are denoted by the same or similar reference numerals, and the description thereof is omitted as appropriate, except where specifically indicated. In addition, the differences from the embodiments described above will be mainly described below, and similar functions and effects of the same components as in the embodiments described above will not be mentioned each time.

The optical sensor 400 of the present embodiment is a limited reflection type photoelectric sensor. As illustrated in FIG. 16, the light projecting unit 11 and the light receiving unit 21 are housed in the same housing, defined as a light projector and receiver 410. The axis of light emitted from the light projecting unit 11 of the light projector and receiver 410 (hereinafter also referred to as “projecting axis”) and the axis of light incident on the light receiving unit 21 of the light projector and receiver 410 (hereinafter also referred to as “receiving axis”) intersect with each other. More specifically, the receiving axis of the light receiving unit 21 and the projecting axis of the light projecting unit 11 are configured to intersect with each other so that the area where the light beam and the light receiving field intersect with each other, is limited. In FIG. 18, the projecting axis of the light projecting unit 11 is illustrated as a one dot chain line, and the receiving axis of the light receiving unit 21 is illustrated as a two dot chain line. The area where the range of light emitted from the light projecting unit 11 and the light receiving area of the light receiving unit 21 overlap with each other, becomes the detection area. In the example illustrated in FIG. 18, the limited area of the rectangle surrounded by the light range illustrated by the thick line and the light receiving area illustrated by the dotted line is a detection area DA. When the target object TA exists in the detection area DA, the light beam emitted from the light projecting lens 16 in the light projecting unit 11 from the package 13, in which the light source 12 is installed on the bottom surface 13b, is reflected by the target object TA and returned to the light projector and receiver 410. This reflected light is received by the light receiving unit 21 through the light receiving lens 26, so that the amount of the reflected light received by the light receiving unit 21 increases compared to when the target object TA does not exist in the detection area DA. The detection unit 40 is configured to detect the target object TA and generate a detection signal for the target object TA based on the change in the amount of reflected light received.

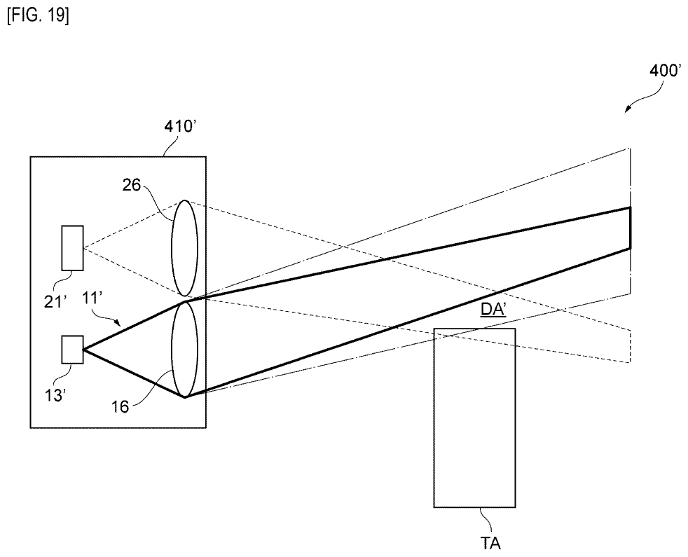

Next, the effect of stray light in the known optical sensor will be described with reference to FIG. 19. FIG. 19 is a diagram for describing the influence of stray light in the known optical sensor 400′. Note that the known optical sensor 400′ in FIG. 19 is a limited reflection type photoelectric sensor, and only the light projector and receiver 410′ provided in the known optical sensor 400′ is illustrated for simplicity of description.

As illustrated in FIG. 19, if the light emitted from the package 13′ and the light projecting lens 16 in the light projecting unit 11′ includes stray light indicated by one dot chain line, the detection area expands. In the example illustrated in FIG. 19, the detection area DA′ extends into a rectangular area surrounded by the range of stray light indicated by one dot chain line and the light receiving area indicated by a dotted line. Thus, the target object TA which is, under normal conditions, outside the range of the detection area is included in the detection area DA′. Stray light is not intended in the design, so that it is difficult to maintain the limitation of the detection area.

On the other hand, in the optical sensor 400 of the present embodiment, the receiving axis of the light receiving unit 21 and the projecting axis of the light projecting unit 11 are configured to intersect with each other so that the area where the light beam and the light receiving field intersect with each other is limited. This solves the problem that it is difficult to achieve the area limitation when there is stray light.

### Fifth Embodiment

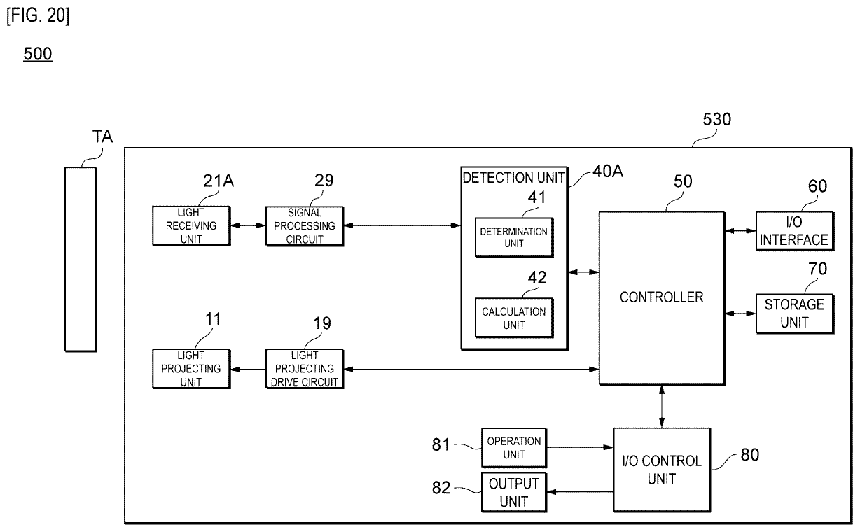

Next, the configuration of an optical sensor according to the fifth embodiment will be described with reference to FIG. 20. FIG. 20 is a block diagram illustrating a schematic configuration of an optical sensor 500 according to the fifth embodiment. In the fifth embodiment, the same or similar components as in the embodiments described above are denoted by the same or similar reference numerals, and the description thereof is omitted as appropriate, except where specifically indicated. In addition, the differences from the embodiments described above will be mainly described below, and similar functions and effects of the same components as in the embodiments described above will not be mentioned each time.

The optical sensor 500 according to the present embodiment is a distance setting type photoelectric sensor. As illustrated in FIG. 20, the optical sensor 500 includes a main body 530. The main body 530 includes the light projecting unit 11, the light projecting drive circuit 19, a light receiving unit 21A, the signal processing circuit 29, a detection unit 40A, a control unit 50, an I/O interface 60, a storage unit 70, the I/O control unit 80, an operation unit 81, and an output unit 82, which are all accommodated in the same housing.

The light receiving unit 21A is configured such that a plurality of pixels receive light and the amount of the received light can be detected for each pixel. In addition, the light receiving unit 21A is configured to obtain a received light amount distribution signal indicating the amount of the received light for each pixel, which will be described below. The light receiving unit 21A includes, for example, an image sensor. The image sensor is, for example, a CMOS (Complementary MOS) image sensor or a CCD (Charge-Coupled Device) image sensor. The image sensor includes a plurality of pixels, and each pixel is arranged in one or two dimensions. Each pixel accumulates a charge according to the amount of the received light during a predetermined exposure time. Each pixel outputs an electric signal according to the accumulated charge.

The detection unit 40A includes the determination unit 41 and a calculation unit 42 as functional blocks. The received light amount distribution signal obtained by the light receiving unit 21A is input to the detection unit 40 via the signal processing circuit 29. The detection unit 40A is configured to detect the target object TA based on the change of the received light amount distribution signal. Note that details of the determination unit 41 and the calculation unit 42 will be described below.

In the example illustrated in FIG. 20, the determination unit 41 and the calculation unit 42 are illustrated to be functional blocks of the detection unit 40A, but are not limited thereto. For example, the determination unit 41 and the calculation unit 42 may be configured as independent elements of each other. The light projecting drive circuit 19, the light receiving unit 21A, the signal processing circuit 29, the determination unit 41, the calculation unit 42, the control unit 50, and the I/O control unit 80 are not limited to independent elements of each other. For example, at least two of the light projecting drive circuit 19, the light receiving unit 21A, the signal processing circuit 29, the determination unit 41, the calculation unit 42, the control unit 50, and the I/O control unit 80 may be configured as an integral unit. More specifically, the light receiving unit 21A, the signal processing circuit 29, and the determination unit 41 may be configured as an integral unit including a processor such as an ASIC, and the light projecting drive circuit 19, the calculation unit 42, the control unit 50, and the I/O control unit 80 may be configured as an integral unit including a processor such as an ASIC. Alternatively, the light projecting drive circuit 19, the light receiving unit 21A, the signal processing circuit 29, and the calculation unit 42 may be configured as an integral unit including a processor such as an ASIC, and the determination unit 41, the control unit 50, and the I/O control unit 80 may be configured as an integral unit including a processor such as an ASIC.

The optical sensor 200, the optical sensor 300, and the optical sensor 400 described above may be configured in the same manner as the optical sensor 500 of the present embodiment.

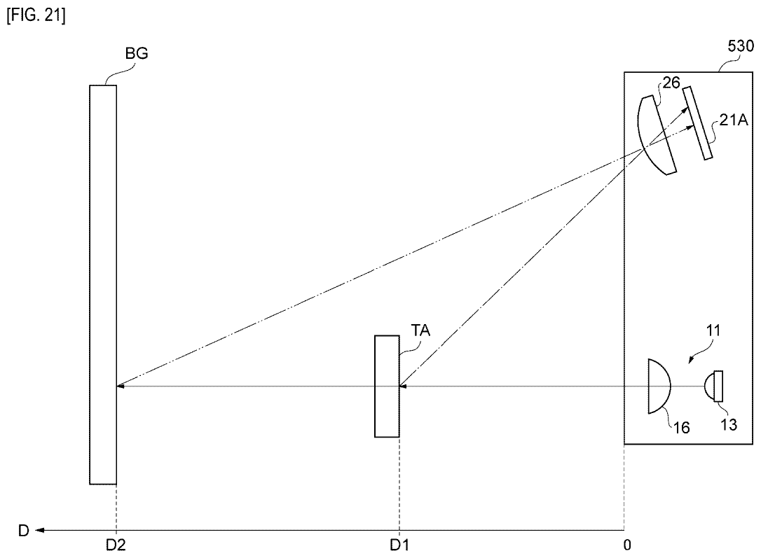

The principle of target object detection by the optical sensor according to the fifth embodiment will now be described with reference to FIG. 21. FIG. 21 is a diagram for describing the detection principle of the optical sensor 500 according to the fifth embodiment.

As illustrated in FIG. 21, the main body 530 of the optical sensor 500 is disposed away from the target object TA by a predetermined distance D1 in advance. In the light projecting unit 11, the light beam, through the light projecting lens 16, emitted from the package 13 in which the light source 12 is installed on the bottom surface 13b, is reflected by the target object TA. The reflected light enters some pixels of the light receiving unit 21A through the light receiving lens 26. On the other hand, a background BG, for example, is disposed away from the main body 530 by the distance D2 (distance D2>distance D1). The light reflected by the background BG enters another pixel of the light receiving unit 21A through the light receiving lens 26. Thus, each pixel of the light receiving unit 21A arranged in one dimension, in the vertical direction in the example of FIG. 21, corresponds to a distance D from the main body 530. In the example illustrated in FIG. 21, each pixel of the light receiving unit 21A may be arranged in two dimensions in the vertical direction and the depth direction (perpendicular direction to the paper surface). Thus, by arranging each pixel of the light receiving unit 21A in one dimension or two dimensions, a received light amount distribution signal indicating the light receiving amount for each pixel, that is, a received light amount distribution signal, which indicates the light receiving amount corresponding to the distance D from the main body 530, can be obtained.

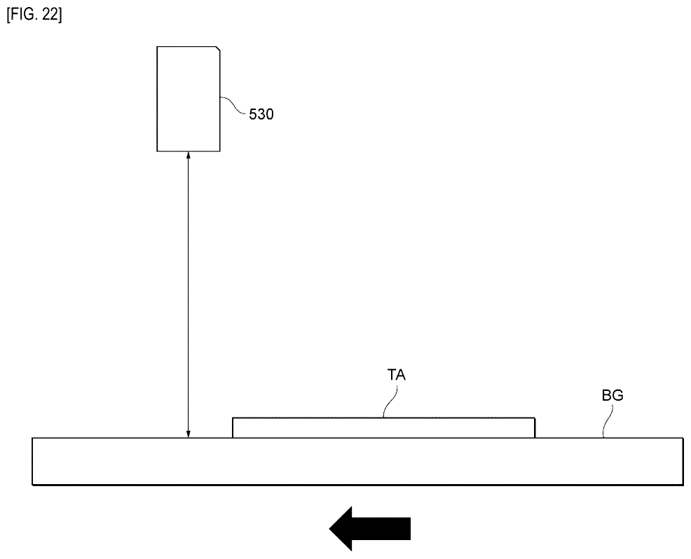

Next, an application example of the optical sensor according to the fifth embodiment will be described with reference to FIG. 22. FIG. 22 is a schematic diagram illustrating an application example of the optical sensor 500 according to the fifth embodiment.

As illustrated in FIG. 22, the main body 530 of the optical sensor 500 is disposed above the background BG, and is disposed so as to project light toward the background BG and receive reflected light. The target object TA is placed on the background BG, and the background BG on which the target object TA is placed moves in the direction of the black arrow illustrated in FIG. 22.

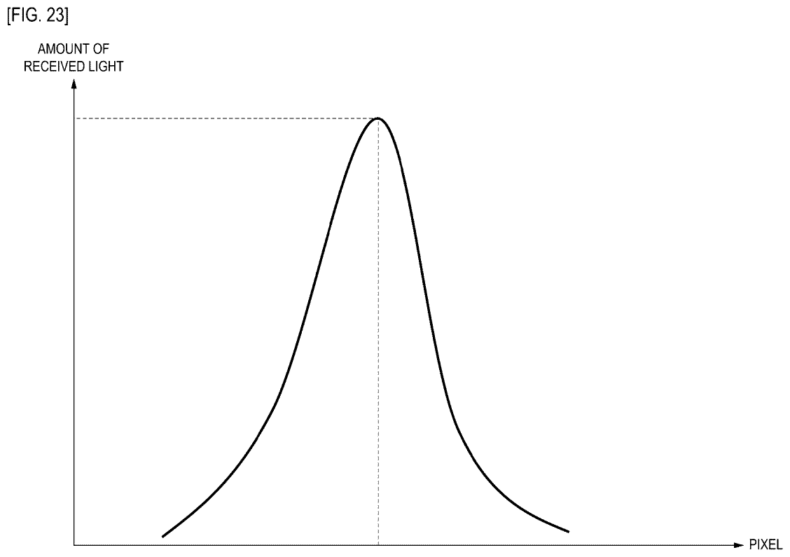

Now, referring to FIG. 23, the distance based on the received light amount distribution signal will be described. FIG. 23 is a waveform diagram illustrating an example of the received light amount distribution signal. In FIG. 23, the horizontal axis represents each pixel of the light receiving unit 21A, and the vertical axis represents the amount of the received light.

As illustrated in FIG. 23, the received light amount distribution signal usually has a waveform in which the amount of the received light of a pixel peaks. The pixel of the peak amount of received light in the received light amount distribution signal obtained from the light receiving unit 21A is the pixel into which the light emitted from the main body 530 and reflected by the target object TA enters. The pixel corresponds to the distance from the main body 530 to the target object TA.

Specifically, the calculation unit 42 of the detection unit 40A calculates the coordinates of the center of gravity in the received light amount distribution signal. Then, the calculation unit 42 converts the calculated coordinates into a distance. In this way, the calculation unit 42 can calculate the distance from a light projector and receiver 510 to the target object TA.

The determination unit 41 of the detection unit 40A determines whether the distance calculated by the calculation unit 42 based on the maximum peak in the received light amount distribution signal is within a predetermined range (±ΔD) from the predetermined distance D1 of the target object TA. In this way, the detection unit 40A can detect the target object TA located at the distance D1 from the light projector and receiver 510.

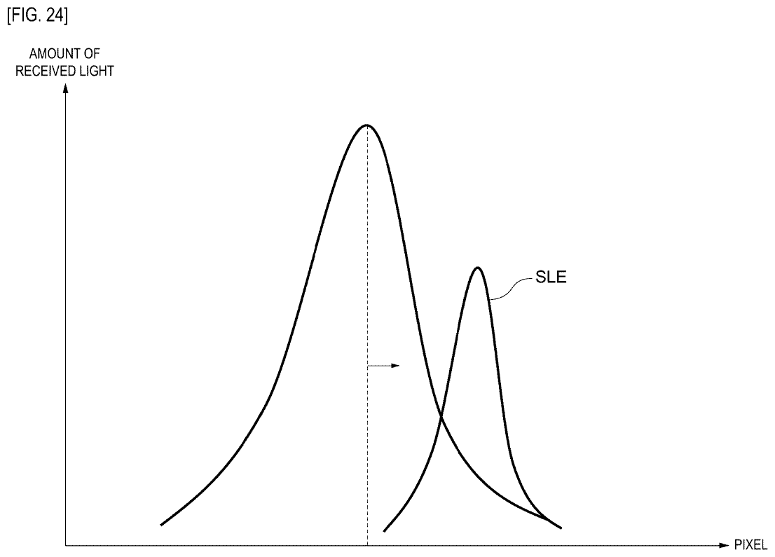

Next, the influence of stray light in the known optical sensor will be described with reference to FIG. 24. FIG. 24 is a waveform diagram for describing the influence of stray light in the known optical sensor. The known optical sensor in FIG. 24 is a distance setting type photoelectric sensor, and the light receiving unit is configured to obtain a received light amount distribution signal for each pixel for the received light. In FIG. 24, the horizontal axis represents each pixel of the light receiving unit, and the vertical axis represents the amount of the received light.

If a stray light is included in the light emitted from the light projecting unit, the irradiation range of the projected light is expanded, and the stray light may be reflected by the background BG described above and incident on the light receiving unit. In addition, if the surface of the target object TA is a packaging, and this packaging includes colors or patterns with different reflectance, these colors and patterns may reflect stray light, and the reflected light of the stray light may be incident on the light receiving unit. In these cases, as illustrated in FIG. 24, the received light amount distribution signal of the light receiving unit includes a stray light component SLE in addition to the main light component. Thus, the center of gravity in the received light amount distribution signal may fluctuate, and the calculated distance may change, resulting in false determination of the presence or absence of the target object TA.

On the other hand, in the optical sensor 500 of the present embodiment, the light projecting unit 11 emits the light beam toward the outside, the light receiving unit 21A is configured such that each of the plurality of pixels can detect the amount of the received light, and the received light amount distribution signal for each pixel is obtained for the received light, and the detection unit 40A detects the target object TA based on this obtained received light amount distribution signal. As described above, the light incident on the side surface 13c from the light source 12 installed on the bottom surface 13b is absorbed, so that the stray light component SLE in the received light amount distribution signal can be reduced and the fluctuation of the center of gravity in the received light amount distribution signal can be reduced, and thus false detection of the target object TA can be decreased.

Thus, exemplary embodiments of the present disclosure have been described. The optical sensor 100 according to one embodiment, includes the light projecting unit 11, the light receiving unit 21, and the detection unit 40.

The light projecting unit 11 includes the light source 12 that emits light and the light projecting lens 16 configured to condense the light emitted from the light source 12.

The light receiving unit 21 receives the light, and the detection unit 40 detects the target object TA based on the received light.

The light projecting unit 11 further includes the package 13 having a recessed portion 13a.

The light source 12 is mounted on the bottom surface 13b of the recessed portion. The light projecting unit also includes the resin 14 that is light transmissive and covers the light source 12.

The side surface 13c of the recessed portion 13a includes a material that absorbs the light emitted from the light source 12. As a result, the light emitted from the light source 12 installed on the bottom surface 13b and incident on the side surface 13c is absorbed, making it possible to reduce stray light that passes through the side surface 13c, which is the main factor in stray light generation. Therefore, stray light can be reduced, and a decrease in the S/N ratio can be reduced. In addition, the visibility of the spot of the main light irradiated on the target object TA or the like can be improved.

Note that the above-described embodiments are provided for facilitating understanding of the present disclosure, and is not intended to limit the interpretation of the disclosure. The present disclosure may be modified/improved without departing from the gist thereof, and the present disclosure also includes equivalents thereof. In other words, such variations that are obtained by those skilled in the art appropriately making a design change to the embodiment are also included in the scope of the present disclosure as long as the variations include the features of the present disclosure. For example, each element included in the embodiment as well as the arrangement, material, condition, shape, size, and the like of each element are not limited to those exemplified and may be changed appropriately. The respective embodiments are merely illustrative, and it goes without saying that partial replacements or combinations of configurations illustrated in different embodiments are allowed, and these are also included in the scope of the present disclosure as long as these include the features of the present disclosure.

### Supplementary Note

An optical sensor (100, 200,300, 400, 500) includes a light projecting unit (11), a light receiving unit (21, 21A), and a detection unit (40).

The light projecting unit (11) includes a light source (12) that emits light and the light projecting lens (16) configured to condense the light emitted from the light source (12).

The light receiving unit (21) receives the light, and the detection unit (40, 40A) detects a target object (TA) based on the received light.

The light projecting unit (11) further includes a package (13) having a recessed portion (13a).

The light source (12) is mounted on the bottom surface (13b) of the recessed portion (13a).

The light projecting unit (11) also includes a resin (14) that is light transmissive and covers the light source (12).

A side surface (13c) of the recessed portion (13a) includes a material that absorbs the light emitted from the light source (12).

1. An optical sensor, comprising:
a light projecting unit, comprising:
a light source that emits light; and
a light condensing element configured to condense the light emitted from the light source;
a light receiving unit that receives the light; and
a detection unit configured to detect a target object based on the received light,
wherein the light projecting unit further comprises:
a package formed with a recessed portion having a bottom surface on which the light source is mounted; and
a resin that is light transmissive and covers the light source, and
wherein a side surface of the recessed portion comprises a material that absorbs the light emitted from the light source.

2. The optical sensor according to claim 1, wherein:
the side surface is connected to the bottom surface and forms an angle greater than 90 degrees with the bottom surface.

3. The optical sensor according to claim 1, wherein:
the side surface has a reflectance of 10% or less with respect to the light emitted from the light source.

4. The optical sensor according to claim 1, wherein:
the side surface is a rough surface.

5. The optical sensor according to claim 1, wherein:
the package is formed of a material that absorbs the light emitted from the light source.

6. The optical sensor according to claim 1, wherein:
the package is formed of a material that absorbs the light emitted from the light source,
has a metal electrode pattern on the bottom surface, and
the light source is connected to the metal electrode pattern.

7. The optical sensor according to claim 1, wherein:
the light projecting unit and the light receiving unit are provided in separate housings,
the light projecting unit is configured to emit a light beam toward the outside, the light receiving unit is configured to receive light emitted from the light projecting unit, and
the detection unit is configured to detect the target object based on a change in amount of the received light.

8. The optical sensor according to claim 1, wherein:
the light projecting unit and the light receiving unit are provided in a common housing,
the light projecting unit is configured to emit a light beam toward a retroreflective plate,
the light receiving unit is disposed to receive light reflected by the retroreflective plate, and
the detection unit is configured to detect the target object based on a change in amount of the received light.

9. The optical sensor according to claim 1, wherein:
the light projecting unit and the light receiving unit are provided in a common housing,
the light projecting unit is configured to emit a light beam toward the outside,
the light receiving unit has a light receiving field and is disposed to receive reflected light from a region where the light beam and the light receiving field intersect with each other, and
the detection unit is configured to detect the target object based on a change in amount of the received light.

10. The optical sensor according to claim 9, wherein:
a receiving axis of the light receiving unit and a projecting axis of the light projecting unit are configured to intersect with each other in a manner that the region where the light beam and the light receiving field intersect with each other is limited.

11. The optical sensor according to claim 1, wherein:
the light projecting unit is configured to emit a light beam toward the outside,
the light receiving unit comprises a plurality of pixels, each configured to detect an amount of received light, and is further configured to obtain a received light amount distribution signal for each pixel for the received light, and
the detection unit is configured to detect the target object based on the received light amount distribution signal.
